(19) United States
(12) Patent Application Publication
(10) Pub. No.: US 2018/0192533 A1
(43) Pub. Date: Jul. 5, 2018

(54) CASE FOR HOUSING ELECTRIC BOARD

(71) Applicant: NORITZ CORPORATION, Hyogo (JP)

(72) Inventor: Mitsuhisa YOKOZEKI, Akashi-shi (JP)

(73) Assignee: NORITZ CORPORATION, Hyogo (JP)

(21) Appl. No.: 15/842,963

(22) Filed: Dec. 15, 2017

(30) Foreign Application Priority Data
Jan. 4, 2017 (JP) 2017-000113
Mar. 2, 2017 (JP) 2017-038963

(51) Int. Cl. H05K 5/03; H05K 5/00; H05K 5/02; H05K 5/06; H05K 7/14

(52) U.S. Cl. CPC H05K 5/03; H05K 5/0004; H05K 7/1427; H05K 5/0204; H05K 5/063; H05K 5/0221

(57) ABSTRACT

A case for housing an electric board of the present invention includes: a case body with a front side opened for housing an electric board inside the case body; and a lid that closes a front side of the case body, the case body having a guide portion for sliding and moving the lid parallel to the front side, and a locking portion that locks the lid slid along the guide portion, the lid having a sliding portion that slides along the guide portion, and an engaging portion that engages with the locking portion while the front side of the case body is closed. The case further includes a restricting portion provided between an inner surface of the lid and the case body to restrict sliding movement of the lid in an opening direction of the lid.

### TECHNICAL FIELD

The present invention relates to a case for housing an electric board.

### BACKGROUND ART

Conventionally, a case for housing various electric boards has been used in various fields. This type of case generally includes a box-shaped case body with one side opened and a lid for closing an opening of the case body. As this type of prior art, there is a case used for antenna related equipment such as a booster and a mixer (refer to Japanese Unexamined Patent Publication No. S58-79800, for example). This case includes a box-shaped case body with one side opened and a sliding lid that is slid so as to open and close an opening of the case body while being fitted to the case body. The sliding lid is provided on its back surface with a plurality of projections in its sliding direction so that sliding movement of the sliding lid can be locked.

As another prior art, there is a case for an electronic circuit module, including a box-shaped bottom lid (case body), an upper lid (lid) fitted to the bottom lid, and a rail portion provided on a side surface portion of the upper lid, wherein the upper lid is slid to close an opening of the bottom lid while the rail portion surrounds a bottom surface of the bottom lid (refer to Japanese Unexamined Patent Publication No. H6-177553, for example). This case includes an upper lid fixture provided between a side surface portion of the bottom lid and the side surface portion of the upper lid.

There is also known a case that houses an electric component, and has a waterproof structure. As such a case, a case for an automatic water supply device is known (refer to, Japanese Unexamined Patent Publication No. H10-311070, for example). This automatic water supply device includes a battery box with a front side opened, being provided in a recess of the case, and a waterproof groove formed around the battery box. When a lid is attached to the recess, a front side of each of the battery box and the waterproof groove is covered. According to this structure, the waterproof groove prevents water entry into the battery box.

### SUMMARY OF INVENTION

### Technical Problem

### First Problem to be Solved

A substrate component such as an IC card (memory IC built-in card) may be sometimes mounted on an electric board to be housed inside a case for housing an electric board. Thus, a case for housing an electric board, installed indoors, requires a lid that can be easily detached from the case at the time of maintenance. Meanwhile, a case for housing an electric board, installed outdoors, often requires an antitheft structure for a substrate component in addition to detaching of a lid for maintenance.

However, according to the prior arts described in Japanese Unexamined Patent Publication No. S58-79800 and Japanese Unexamined Patent Publication No. H6-177553, a portion where the lid is fixed to the case body can be easily detached, and thus when the case is installed outdoors, the lid may be opened to cause a substrate component to be stolen. As a countermeasure against this, it is conceivable to fix the lid to the case body with a screw, for example. However, when a case for housing an electric board is installed outdoors, a design of the case is also important. Thus, when screws for theft prevention are exposed on an outer surface of the case, a design of the case may be degraded.

### Second Problem to be Solved

While a conventional case described in Japanese Unexamined Patent Publication No. 10-311070 enables water flowing through a waterproof groove to be prevented from entering a battery box, water may enter the inside of the battery box by movement of water due to a capillary phenomenon between a lid and a front end surface of the battery box. This problem is common to a case for housing an electric board including a case body and a lid.

The present invention has been made to solve the first and second problems to be solved, and it is a first object of the present invention to provide a case for housing an electric board, the case preventing a lid from being easily opened by providing a structure between a case body and the lid to restrict an opening operation of the lid without degrading a design of the case for housing an electric board.

It is a second object of the present invention to provide a case for housing an electric board, the case including a case body and a lid to enable rainwater to be prevented from entering into the case body due to a capillary phenomenon.

### Solution to Problem

To achieve the first object, a case for housing an electric board according to an aspect of the present invention includes: a case body with a front side opened for housing an electric board inside the case body, a lid that closes the front side of the case body, and a restricting portion provided between an inner surface of the lid and the case body to restrict sliding movement of the lid in an opening direction of the lid, the case body including a guide portion for sliding and moving the lid parallel to the front side, and a locking portion that locks the lid slid along the guide portion, and the lid including a sliding portion that slides along the guide portion, and an engaging portion that engages with the locking portion while the front side of the case body is closed. The term, “electric board”, in the document of the present specification and the scope of claims includes a board on which an electronic component is fixed, a board on which an IC card incorporating a memory IC or the like is mounted, and the like.

This configuration allows the sliding portion of the lid to be slid along the guide portion of the case body to engage the engaging portion of the lid with the locking portion of the case body, so that an opening of the case body can be closed by the lid. Then, the restricting portion can restrict sliding of the lid in the opening direction of the lid at a position different from the engaging portion at which the lid is engaged with the case body, so that it is possible to prevent the lid from easily sliding and moving with respect to the case body. In addition, the restricting portion is provided between the inner surface of the lid and the case body, so that the restricting portion is not exposed to an outer surface of the case, and thus a design of the case for housing an electric board does not degrade. As a result, the case for housing an electric board can be provided with an anti-theft structure while considering design.

The restricting portion also may include a recess provided in at least one of the case body and the lid, and a protrusion provided in the other of the case body and the lid at a position corresponding to the recess in a state in which the lid is closed. This configuration causes the recess and the protrusion to fit with each other when the opening of the case body is closed by the lid, thereby restricting sliding movement of the lid in the opening direction of the lid. As a result, it is possible to achieve a configuration that prevents the lid from being easily detached from the case body with a simple structure.

The protrusion may be configured to be detachable. This configuration enables restriction of sliding movement of the lid in the opening direction of the lid by the restricting portion to be released by removing a portion of the restricting portion, restricting sliding of the lid in the opening direction of the lid. This easily enables sliding of the lid to be prevented from being restricted when sliding of the lid does not need to be restricted. As a result, the case for housing an electric board requiring no anti-theft structure enables the lid to be easily detached.

The protrusion also may be configured to be capable of adjusting a height of the protrusion protruding toward the recess. This configuration causes a fitted height of the protrusion and the recess of the restricting portion to be changed by adjusting a height of the protrusion, so that it is possible to adjust force for restricting sliding movement of the lid.

In addition, the protrusion may be formed of a screw member having a head portion. This configuration enables a portion for restricting sliding movement of the lid in the opening direction of the lid to be easily provided in the restricting portion.

The screw member may also serve as a fixing screw member for fixing the case body to a mounting surface. This configuration enables the fixing screw member for fixing the case body to the mounting surface to serve not only to fix the case body but also to restrict sliding movement of the lid in the opening direction of the lid.

To achieve the second object, a case for housing an electric board according to another aspect of the present invention includes: a case body in a container shape with a front side opened for housing an electric board inside the case body, the case body including an upper wall portion with an upper surface inclining in at least one direction in a lateral direction, and formed in a stepped shape descending backward in an anteroposterior direction; and a lid for covering the front side of the case body, the lid including a waterproof wall portion that defines a space serving as a drain channel between a first stepped surface of the upper surface formed in a stepped shape and the waterproof wall portion, and that is in contact with or close to a second stepped surface below the first stepped surface.

According to this configuration, the second stepped surface of the upper surface of the upper wall portion of the case body and the waterproof wall portion of the lid are in contact with or close to each other, so that a capillary phenomenon may cause rainwater to enter the inside of the case for housing an electric board through between the second stepped surface and the waterproof wall portion. However, the rainwater entered in such a way exudes into the space between the first stepped surface and the waterproof wall portion, serving as a drain channel, and then flows down along an inclination of a step surface (tread) between the first stepped surface and second stepped surface, being a bottom surface of the space, toward a lateral side of the case body (at least one direction in the lateral direction). As a result, rainwater entry into the case body due to a capillary phenomenon can be prevented.

The lid may include a body portion in a plate shape for covering the front side of the case body, and the waterproof wall portion provided in a upper portion of the body portion, the waterproof wall portion including: an extending wall portion extending backward from a position, above an upper end of the first stepped surface, in the upper portion of the body portion, and having a lower surface inclining in at least one direction in the lateral direction along an upper surface of the case body; and a vertical wall portion extending downward from a leading end of the extending wall portion, and having a front surface being in contact with or close to the second stepped surface.

According to this configuration, it is possible to suitably form a waterproof wall portion that defines a space between the first stepped surface of the upper surface formed in a stepped shape in the upper wall portion of the case body and the waterproof wall portion, the space serving as a drain channel, and that is brought into contact with or comes close to the second stepped surface.

The case body may include a drainage recess formed in the second stepped surface near a lower end of the space so as to extend downward from an upper end of the second stepped surface.

According to this configuration, water flowing down through the space serving as a drain channel can be discharged to the outside of the case for housing an electric board.

The lid may include the extending wall portion that is brought into contact with an upper end surface of the upper surface formed in a stepped shape of the case body, and the vertical wall portion with a lower end positioned above a lower end of the second stepped surface.

According to this configuration, the lower end of the vertical wall portion of the lid is positioned above the lower end of the second stepped surface, so that the lower end of the vertical wall portion is not brought into contact with the step surface connecting to the second stepped surface. This causes the extending wall portion of the lid to be reliably brought into contact with the upper end surface of the upper surface formed in a stepped shape of the case body. In addition, the space serving as a drain channel is positioned outside the contact portion in the case for housing an electric board, so that rainwater entry into the case body can be suitably prevented.

The case for housing an electric board may further include a fitting structure in which the lid is fitted to the case body by sliding the lid downward relatively to the case body.

According to this configuration, the following operational effects are achieved. That is, the waterproof wall portion with a leading end extending downward vertically is provided in an upper portion of the lid, so that even if the lid is tried to be fitted to the case body from the front side, the leading end of the waterproof wall portion is brought into contact with an upper portion of the case body, whereby both the lid and the case body cannot be fitted to each other. However, according to this configuration, the fitting structure enables the lid to be fitted to the case body by sliding the lid downward relatively to the case body. In addition, no screw is used to fit the lid to the case body, so that no screw is exposed to an appearance surface. As a result, a design of the case is improved.

### Advantageous Effects of Invention

According to the present invention, the restricting portion can restrict sliding movement of the lid in the opening direction of the lid from the case body when the lid is attached to the case body, thereby enabling the lid to be prevented from being easily detached. In addition, the restricting portion is provided between the case body and the inner surface of the lid, so that a design of the case for housing an electric board does not degrade.

Further, according to the present invention, rainwater entry into the case body due to a capillary phenomenon can be prevented in the case for housing an electric board including the case body and the lid.

### BRIEF DESCRIPTION OF DRAWINGS

FIG. 1 is a front view illustrating a case body of a case for housing an electric board according to a first embodiment of the present invention.

FIG. 2 is a sectional view taken along line II-II illustrated in FIG. 1.

FIG. 3 is an inner view of a lid to be attached to the case body illustrated in FIG. 1.

FIG. 4 is a sectional view taken along line IV-IV illustrated in FIG. 3.

FIG. 5A is a partial rear view illustrating a state before an opening of the case body illustrated in FIG. 1 is closed with the lid illustrated in FIG. 3.

FIG. 5B is a partial rear view illustrating a state where the opening of the case body illustrated in FIG. 1 is closed with the lid illustrated in FIG. 3.

FIG. 6A is a rear view illustrating a case for housing an electric board in a state before an opening of the case body illustrated in FIG. 1 is closed with the lid illustrated in FIG. 3.

FIG. 6B is a rear view illustrating a case for housing an electric board in a state where the opening of the case body illustrated in FIG. 1 is closed with the lid illustrated in FIG. 3.

FIG. 7A is a partial sectional view illustrating a restricting portion provided between the case body illustrated in FIG. 1 and the lid illustrated in FIG. 3 before restriction.

FIG. 7B is a partial sectional view illustrating a state where sliding movement of the lid is restricted by the restricting portion illustrated in FIG. 7A.

FIG. 8 is a partial sectional view illustrating a second example of the restricting portion.

FIG. 9 is a partial sectional view illustrating a third example of the restricting portion.

FIG. 10A is a perspective view illustrating a configuration of a case for housing an electric board according to a second embodiment of the present invention.

FIG. 10B is a front view and a left side view of the case for housing an electric board of FIG. 10A.

FIG. 10C is a rear view of the case for housing an electric board of FIG. 10A.

FIG. 11A is a front view of a case body of the case for housing an electric board of FIG. 10A.

FIG. 11B is a rear view of the case body of the case for housing an electric board of FIG. 10A.

FIG. 12 is a front view illustrating a state where a lid is about to be slid downward relatively to the case body in the case for housing an electric board of FIG. 10A.

FIG. 13 is a rear view and a longitudinal sectional view illustrating a detailed configuration of the case for housing an electric board of FIG. 10A.

FIG. 14 is a partial longitudinal sectional view illustrating a portion B of FIG. 13 in an enlarged manner.

FIG. 15 is a partial perspective view illustrating a drain channel of the case for housing an electric board of FIG. 10A.

FIG. 16 is a partial perspective view illustrating a drainage recess of the case for housing an electric board of FIG. 10A.

### DESCRIPTION OF EMBODIMENTS

### First Embodiment

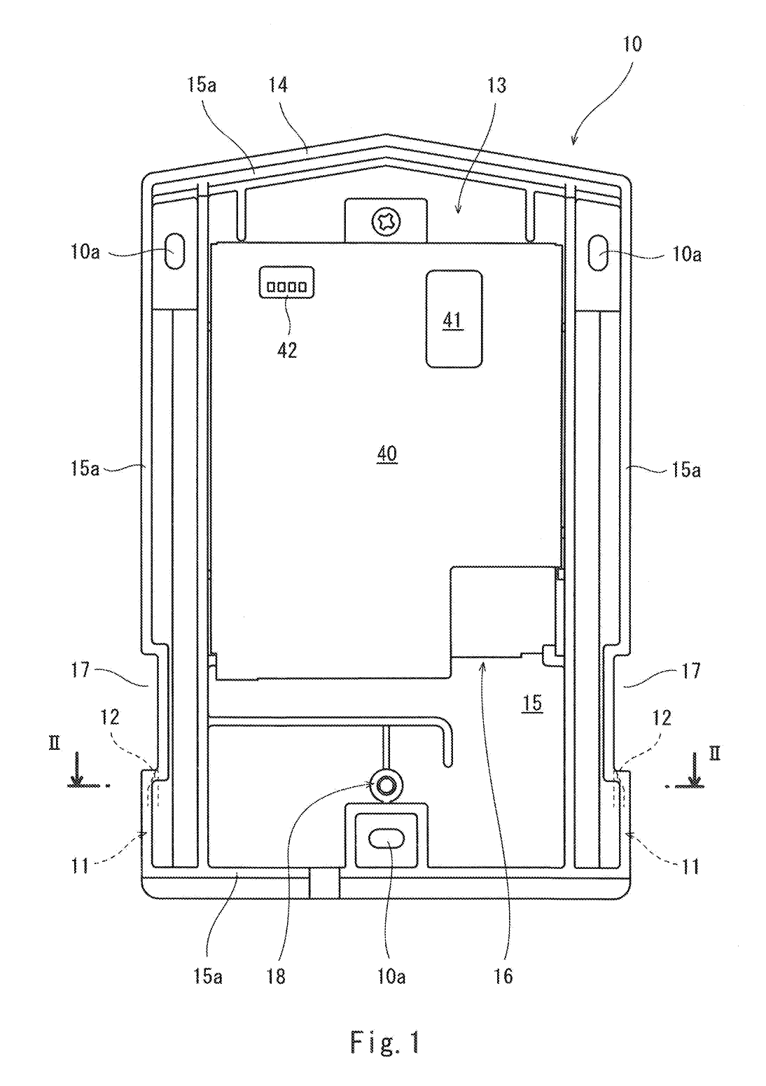

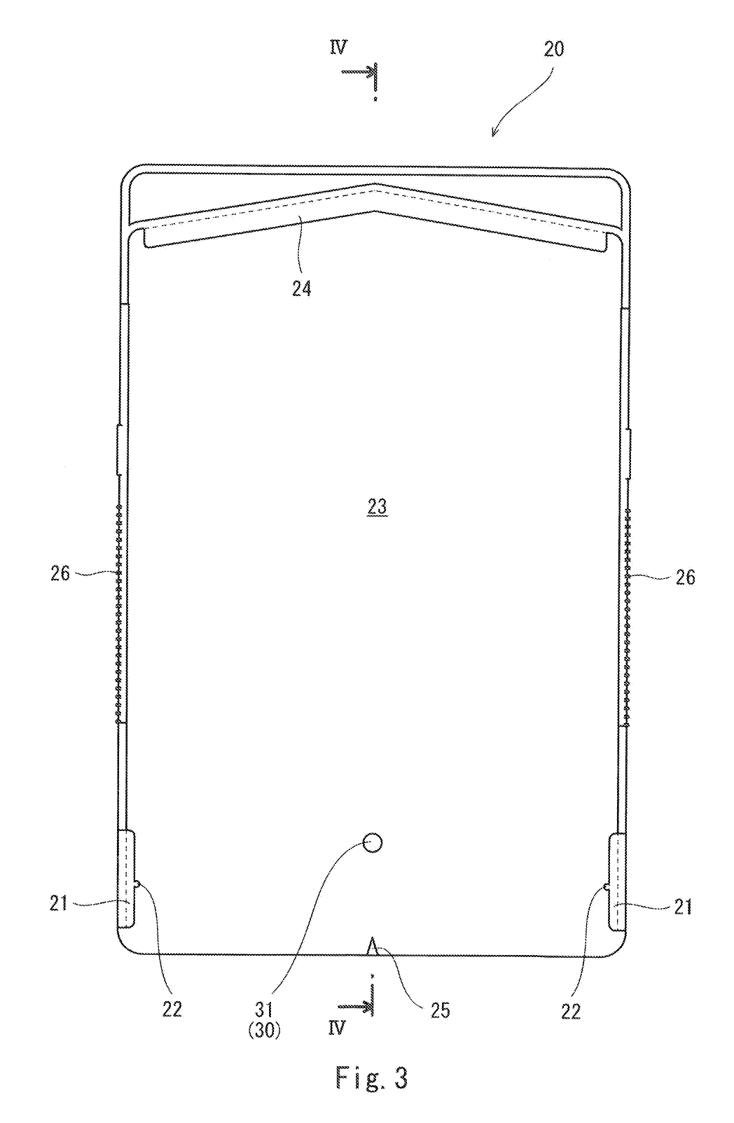

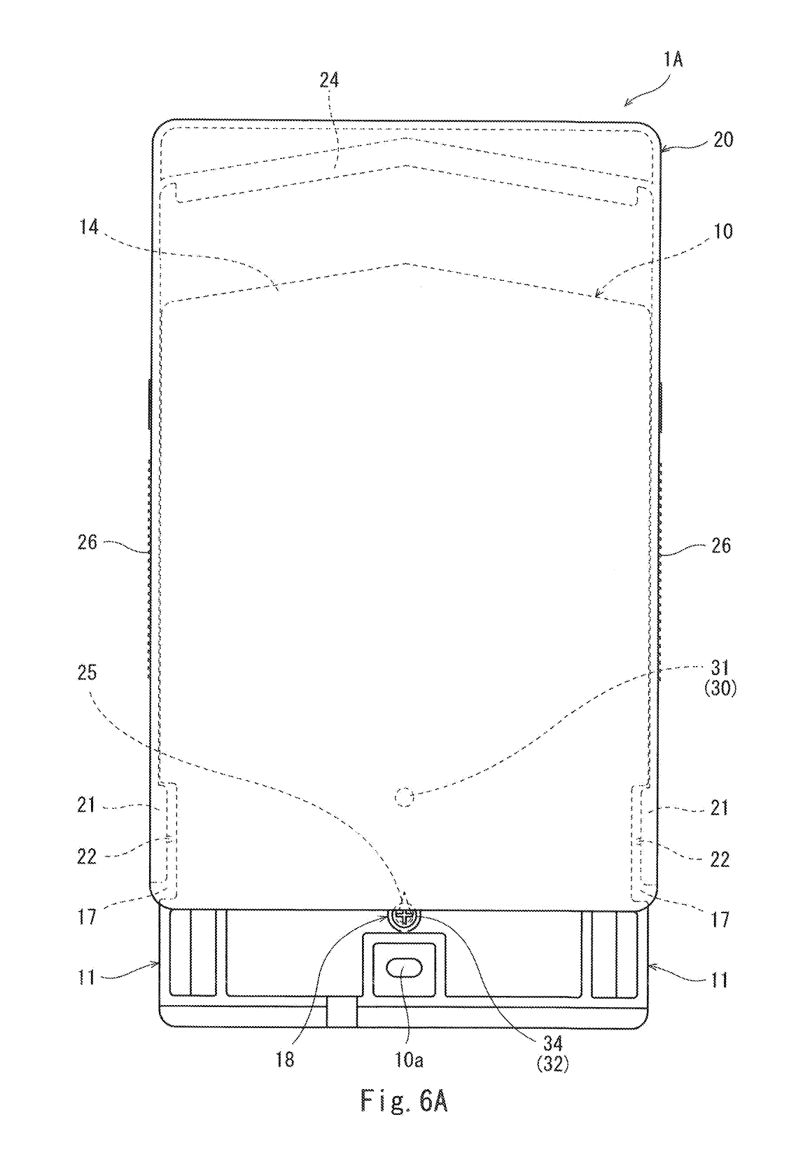

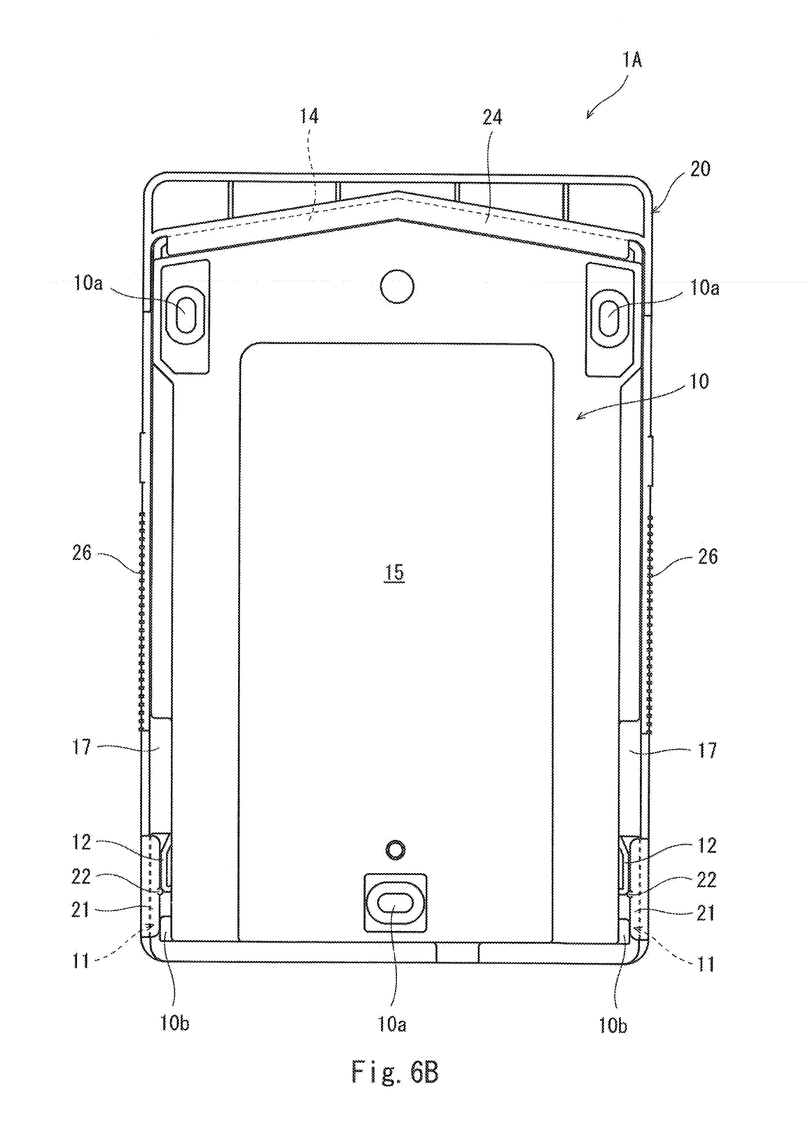

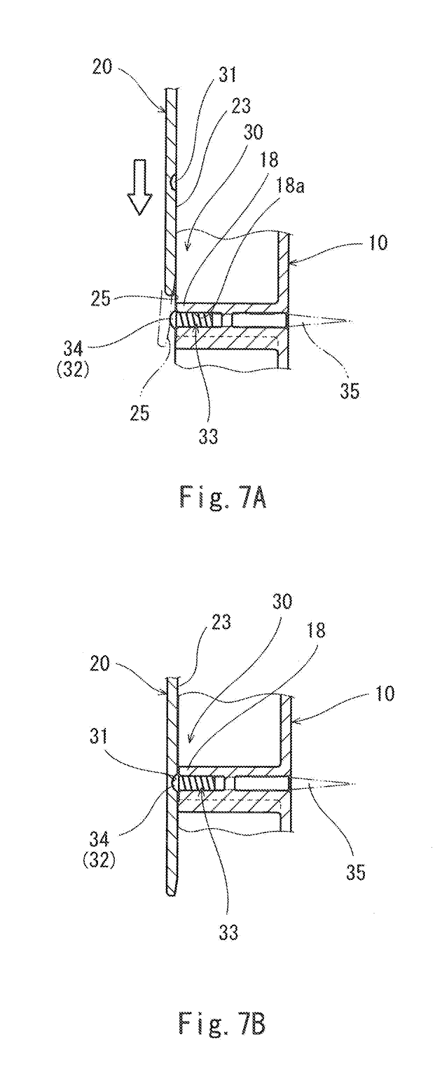

Hereinafter, a first embodiment will be described with reference to the drawings. In the following first embodiment, there is described a case 1A for housing an electric board (refer to FIG. 6A) including: a case body 10 formed in the shape of a vertically elongated and substantially rectangular box in a front view; and a lid 20 having a rectangular shape (refer to FIG. 3) for closing an opening 13 on a front side of the case body 10, for example. In the following first embodiment, there is mainly described an example in which a restricting portion 30 is composed of a recess 31 and a protrusion 32 (refer to FIG. 7A), the case body 10 includes the protrusion 32, and the lid 20 has an inner surface 23 provided with the recess 31. In the present specification and the scope of claims, concepts of a vertical direction, a lateral direction, and an anteroposterior direction coincide with concepts of a vertical direction, a lateral direction, and an anteroposterior direction, in a state facing the case body 10 illustrated in FIG. 1.

[Configuration of Case Body]

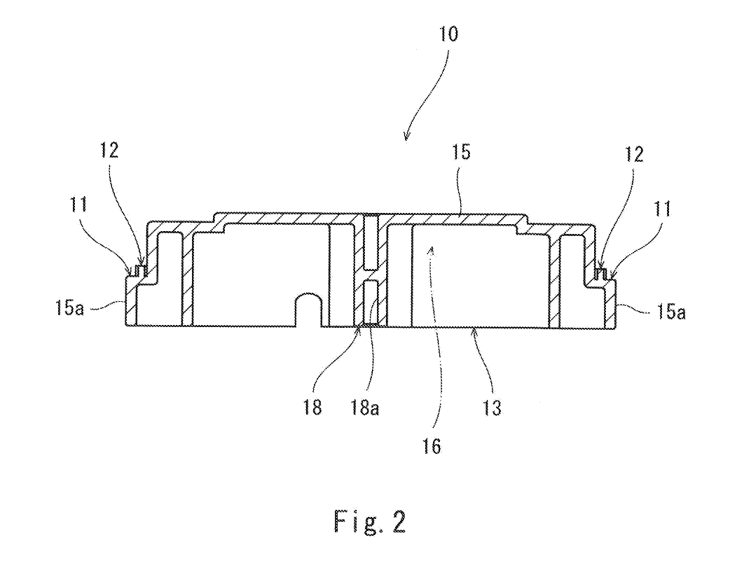

FIG. 1 is a front view illustrating the case body 10 of the case 1A for housing an electric board according to the first embodiment. FIG. 2 is a sectional view taken along line II-II illustrated in FIG. 1. The case body 10 of the first embodiment is formed in a box shape whose front side is the opening 13. The case body 10 has an upper portion including a locking stepped portion 14 formed in a chevron shape with its center projecting upward. The locking stepped portion 14 locks an upper portion of the lid 20 (refer to FIG. 6B).

As also illustrated in FIG. 2, the case body 10 includes a rear wall 15 and a peripheral wall 15a set up forward from a periphery of the rear wall 15, and an internal space in a central portion surrounded by the peripheral wall 15a serves as a housing portion 16 for housing an electric board 40. The electric board 40 is attached to the housing portion 16 with a screw or the like (not illustrated). FIG. 1 illustrates only an IC card 41 and a connector 42 in the electric board 40.

The case body 10 of the first embodiment includes elongated holes 10a at two places right and left of an upper portion thereof and one place in a central portion of a lower portion thereof so that the case body 10 is fixed to a fixing surface (e.g., a wall surface) with a fixing screw member (e.g., a fixing screw) 35 (refer to FIG. 7A). In addition, a locking portion 12 for locking a lower portion of the lid 20 is provided at each of right and left positions in the lower portion of the case body 10. Above the locking portion 12, an insertion portion 17 recessed laterally is provided.

As illustrated in FIG. 2, the locking portion 12 is provided in a guide portion 11 along which an engaging portion 22 (refer to FIG. 3) of the lid 20 vertically moves. The guide portion 11 is provided at a predetermined position in the case body 10 in its thickness direction so as to be parallel to the front side of the case body 10. The guide portion 11 serves as a portion for vertically guiding a sliding portion 21 (refer to FIG. 3) of the lid 20. The guide portion 11 is provided with the locking portion 12 for locking the engaging portion 22 (refer to FIG. 3) of the lid 20. The locking portion 12 is provided on each of right and left sides within a range of the guide portion 11 so as to project. Positioning portions 10b each for laterally positioning a lower end of the lid 20 are provided at a position away from and below the locking portion 12 (refer to FIG. 6B).

In a laterally central portion positioned away from the locking portion 12, there is provided a screw seat 18 for fixing a screw member (such as a screw) 33 with a head portion 34 (refer to FIG. 7A) serving as the protrusion 32 constituting the restricting portion 30 of the case body 10. The screw seat 18 is provided at its central portion with a hollow hole 18a into which the screw member 33 is screwed. The hollow hole 18a may be a through hole. FIG. 2 illustrates a state where the screw member 33 is not attached to the screw seat 18.

[Configuration of Lid]

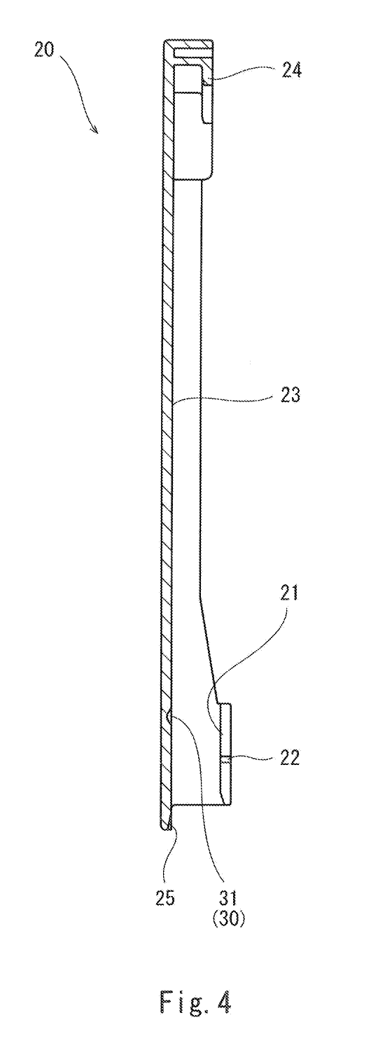

FIG. 3 is an inner view of the lid 20 to be attached to the case body 10. FIG. 4 is a sectional view taken along line IV-IV illustrated in FIG. 3. The lid 20 is formed to have a size enough to close the opening 13 on the front side of the case body 10. The lid 20 is provided in its upper portion with an engaging stepped portion 24 to be engaged with the locking stepped portion 14 in a chevron shape provided in an upper portion of the case body 10. The engaging stepped portion 24 is formed to have an inverted U-shaped section to engage with the locking stepped portion 14 of the case body 10 from above.

The lower portion of the lid 20 is provided at its right and left positions each with the engaging portion 22 to be locked with the locking portion 12 of the case body 10. The engaging portion 22 is provided in the sliding portion 21 that is slid downward along the guide portion 11 formed in the locking portion 12 of the case body 10. The sliding portion 21 is formed to have a size so as to be able to be inserted from the insertion portion 17 of the case body 10 toward the rear of the case body 10.

The lid 20 is provided at its right and left positions each with a gripping portion 26 that is used when the lid 20 is attached to and detached from the case body 10. The gripping portion 26 is provided with nonslip protrusions.

The inner surface 23 of the lid 20 is provided with the recess 31 constituting the restricting portion 30 of the lid 20 side, at a position corresponding to the head portion 34 of the screw member 33 fixed to the screw seat 18 of the case body 10 when the lid 20 is attached to the case body 10 (refer to FIGS. 6B and 7B). In the illustrated example, the recess 31 is a recess 31 having a circular shape. The recess 31 can also be formed in an elliptical shape or a groove shape.

In the first embodiment, a relief 25 is provided at a portion of the lower end of the lid 20, the portion being brought into contact with the head portion 34 of the screw member 33, so that the head portion 34 easily enters an inner surface 23 side of the lid 20 (refer to FIG. 7A for details). The relief 25 of the first embodiment is formed in a tapered shape obliquely cut from the lower end of the lid 20 to a predetermined position (refer to FIG. 4).

[Attachment Structure of Case Body and Lid]

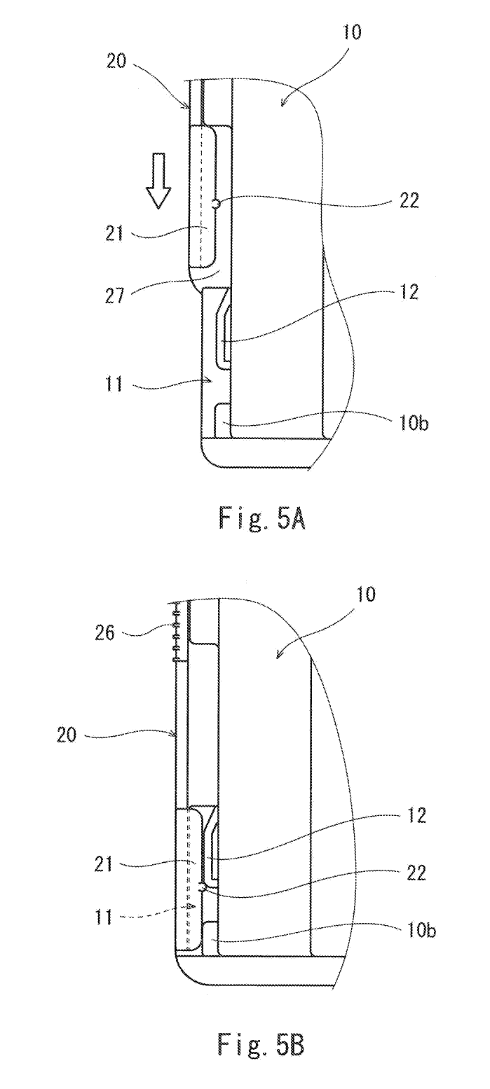

FIG. 5A is a partial rear view illustrating a state before closing the opening 13 (refer to FIG. 1) of the case body 10 with the lid 20. FIG. 5B is a partial rear view illustrating a state where the opening 13 (refer to FIG. 1) of the case body 10 is closed by the lid 20. FIG. 6A is a front view of the case 1A for housing an electric board in a state before closing the opening 13 of the case body 10 with the lid 20. FIG. 6B is a rear view of the case 1A for housing an electric board in a state where the opening 13 of the case body 10 is closed by the lid 20.

As illustrated in FIGS. 5A and 6A, when the opening 13 of the case body 10 is closed with the lid 20, the sliding portion 21 of the lid 20 is inserted backward at the position of the insertion portion 17 of the case body 10. Then, the sliding portion 21 of the lid 20 is slid downward along the guide portion 11 of the case body 10. A relationship between the head portion 34 of the screw member 33 attached to the screw seat 18 of the case body 10 and the recess 31 provided in the inner surface of the lid 20 will be described below with reference to FIGS. 7A and 7B.

As illustrated in FIGS. 5B and 6B, when the sliding portion 21 of the lid 20 is slid downward along the guide portion 11 of the case body 10, the engaging portion 22 provided laterally in the lid 20 passes through the locking portion 12 of the case body 10 to be locked with the lower end. In this state, the lower end of the lid 20 is laterally positioned by the positioning portion 10b of the case body 10.

In addition, when the sliding portion 21 is moved downward along the guide portion 11 of the case body 10 to engage the engaging portion 22 with the locking portion 12 of the case body 10, the engaging stepped portion 24 provided in the upper portion of the lid 20 is engaged with the locking stepped portion 14 provided at the upper portion of the case body 10. This causes the lid 20 to be maintained in a state of being attached to the case body 10 while the upper engaging stepped portion 24, the lower sliding portion 21, and the engaging portion 22 are locked with the case body 10.

[Structure of Restricting Portion]

FIG. 7A is a partial sectional view illustrating the restricting portion 30 provided between the case body 10 and the lid 20 before restriction. FIG. 7B is a partial sectional view illustrating a state where sliding movement of the lid 20 is restricted by the restricting portion 30 illustrated in FIG. 7A.

The state illustrated in FIG. 7A shows the restricting portion 30 in the state illustrated in FIG. 5A. In the case body 10, the screw member 33 is screwed into the hollow hole 18a provided in the screw seat 18. Then, the sliding portion 21 of the lid 20 is slid downward along the guide portion 11 of the case body 10. When the lid 20 is slid downward, the lower end of the lid 20 is brought into contact with the head portion 34 of the screw member 33. The relief 25 is provided in the inner surface 23 of the lid 20, so that after being brought into contact with the head portion 34 of the screw member 33, the lid 20 is slid downward while its central portion is gradually elastically deformed slightly forward by the head portion 34.

The state illustrated in FIG. 7B shows the restricting portion 30 in the state illustrated in FIG. 5B. The lid 20 is slid downward and stopped at a position where the engaging portion 22 is locked with the locking portion 12 of the case body 10. In this state, the recess 31 formed in the inner surface 23 of the lid 20 reaches a position of the head portion 34, and then the head portion 34 is fitted into the recess 31. As a result, the lid 20 is set to a state where the upper engaging stepped portion 24 of the lid 20 is engaged with the locking stepped portion 14 of the case body 10, the lower engaging portion 22 is engaged with the locking portion 12 of the case body 10, and the recess 31 of the lid 20 is locked to the head portion 34 of the screw member 33 attached to the case body 10, at a distant position. Thus, the lid 20 is restricted so that it cannot be easily slid in the opening direction of the lid 20.

As illustrated by a two-dot chain line, as the screw member 33 having the head portion 34 constituting the protrusion 32, the long fixing screw member 35 for fixing the case body 10 to an attachment surface 50 such as a wall surface is available. When the fixing screw member 35 is used, the fixing screw member 35 for fixing the case body 10 to a wall surface or the like can also serve as the protrusion 32 of the restricting portion 30.

According to the case 1A for housing an electric board as described above, when the lid 20 is attached to the case body 10, the recess 31 is fitted into the head portion 34 of the screw member 33 to enable the lid 20 to be prevented from being easily detached from the case body 10. That is, in order to detach the lid 20 from the case body 10, the lid 20 needs to be slid after a central portion of the lid 20 is elastically deformed forward so that a portion provided with the recess 31 can be detached from the head portion 34, thereby enabling the lid 20 to be prevented from being easily detached. Thus, when the case 1A for housing an electric board is attached outdoors or the like, the lid 20 can be prevented from being easily detached for theft prevention.

The configuration for enabling the lid 20 to be prevented from being easily detached is not exposed to an outer surface of the case 1A for housing an electric board, so that a design of the case 1A for housing an electric board is not degraded, thereby enabling an anti-theft structure in consideration of design to be achieved.

When the case 1A for housing an electric board does not require anti-theft measures (e.g., indoor installation, and when an end user detaches the lid 20), the lid 20 can be configured to be easily detached by attaching no screw member 33 to the case body 10.

[Modification of Restricting Portion]

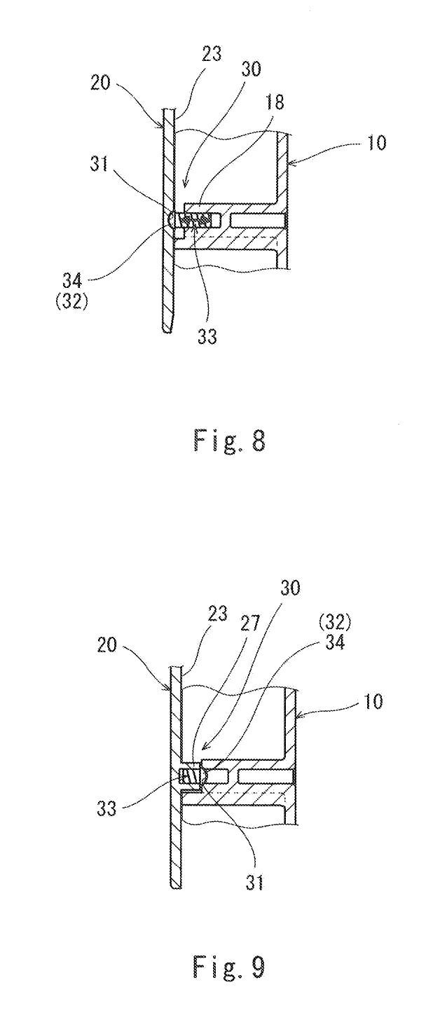

FIG. 8 is a partial sectional view illustrating a second example of the restricting portion 30. FIG. 9 is a partial sectional view illustrating a third example of the restricting portion 30. In each figure, the same component as that of the above-described first embodiment is designated by the same reference numeral for description. As illustrated in FIG. 8, for the restricting portion 30, the amount of screwing of the screw member 33 is adjustable by lowering a height of the screw seat 18, for example. This enables the amount of projecting of the head portion 34 to be adjusted by the amount of screwing of the screw member 33. Adjusting the amount of projecting of the head portion 34 enables the amount of fitting to the recess 31 of the lid 20 to be adjusted. Thus, a sliding force for detaching the lid 20 from the case body 10 is adjustable. This enables a force for detaching the lid 20 to be easily adjusted to be suitable for the case 1A for housing an electric board.

While the head portion 34 of the screw member 33 serves as the protrusion 32 of the restricting portion 30 and the amount of projecting of the head portion 34 is adjustable in this modification, the adjustable protrusion 32 is not limited to the head portion 34 of the screw member 33.

As illustrated in FIG. 9, the restricting portion 30 may be formed such that a screw seat 27 is provided in the inner surface 23 of the lid 20 to fix the screw member 33, and the recess 31 is provided in the case body 10. This also allows the head portion 34 (protrusion 32) of the screw member 33 of the lid 20 to be fitted into the recess 31 of the case body 10 when the lid 20 is attached to the case body 10, thereby enabling the lid 20 to be prevented from being easily detached. One of the lid 20 and the case body 10 may be provided with one of the recess 31 and the head portion 34 of the screw member 33, serving as the protrusion 32, constituting the restricting portion 30. Alternatively, the other one of the lid 20 and the case body 10 may be provided with the other one of the recess 31 and the head portion 34.

### Second Embodiment

Hereinafter, a second embodiment of the present invention will be described with reference to the accompanying drawings. In the following description, the same or corresponding element is designated by the same reference numeral throughout the drawings to omit a duplicated description of the element. The following drawings are arranged as follows for easy understanding of the present invention. In the following drawings, an element that is not related to the present invention may be omitted. In addition, the following drawings may be exaggerated for easy understanding, and a dimensional ratio of an object is not necessarily accurate. Further, the drawings may not strictly coincide with each other.

In the following description, for convenience, a direction from a front side to a back side of the case for housing an electric board is referred to as a forward direction, a direction opposite to the forward direction is referred to as a backward direction, a left direction and a right direction as viewed from the back side of the case for housing an electric board are referred to as a left direction and a right direction, respectively, and an upper direction and a lower direction of the case for housing an electric board are referred to as an upward direction and a downward direction, respectively.

[Configuration]

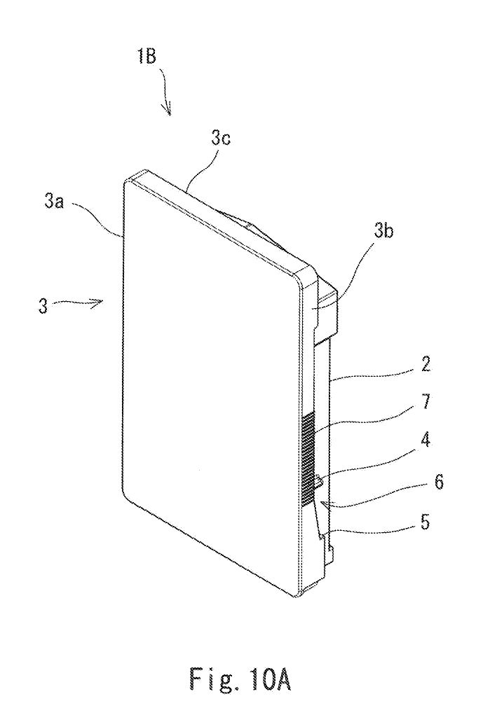

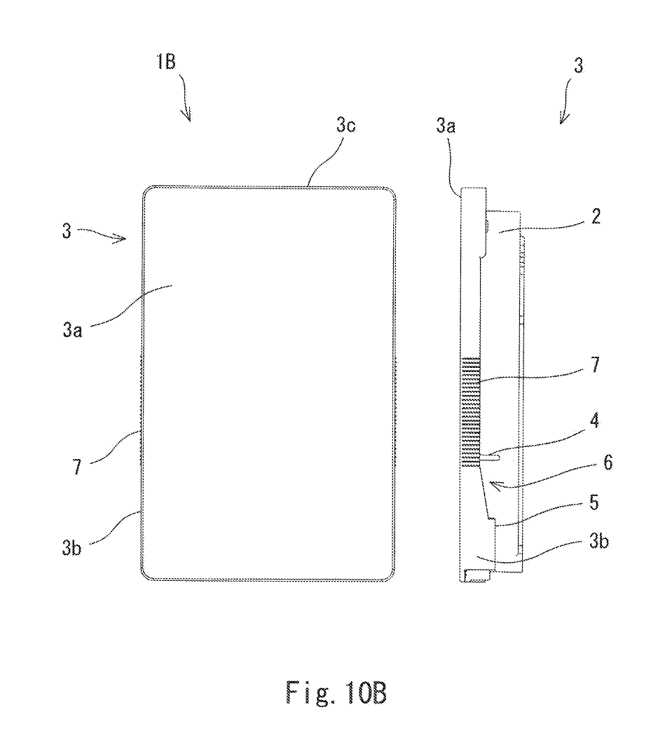

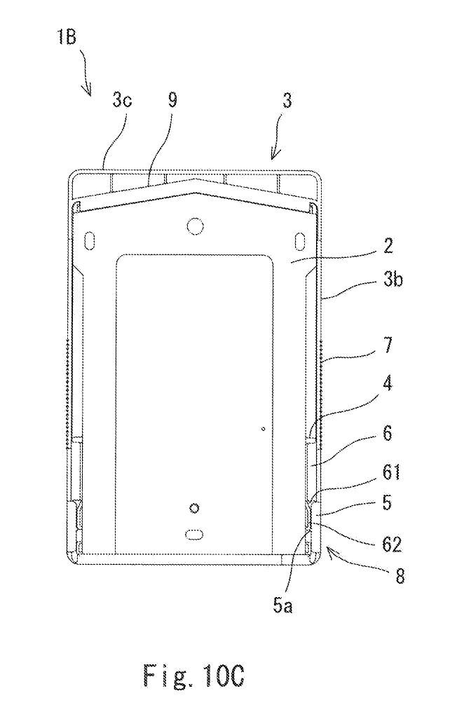

With reference to FIGS. 10A to 10C, the case 1 for housing an electric board according to the second embodiment of the present invention includes a case body 2 and a lid 3.

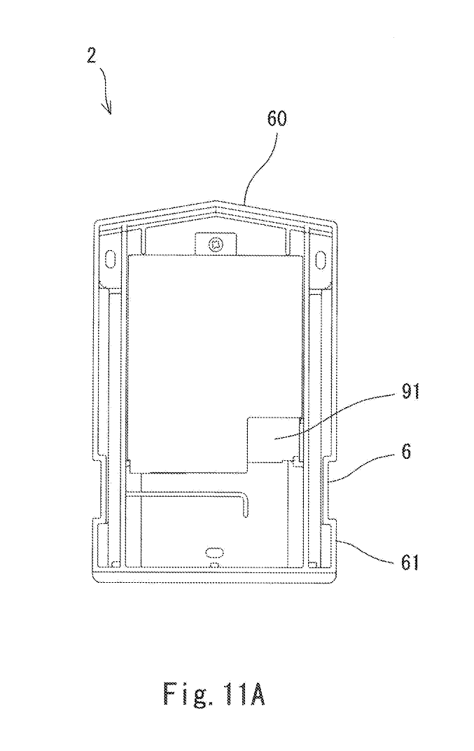

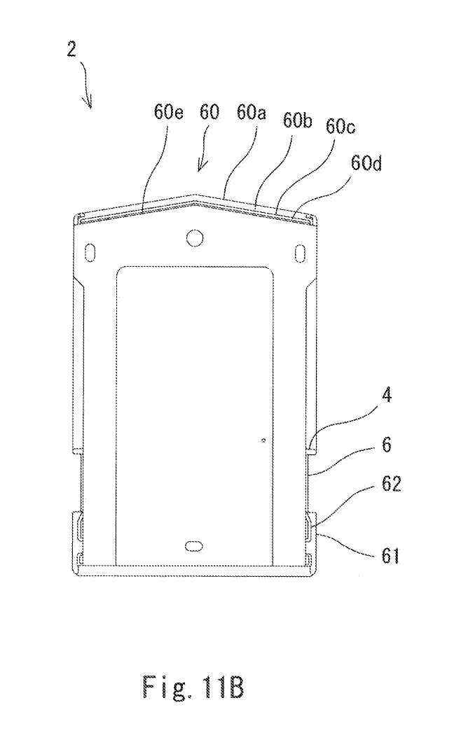

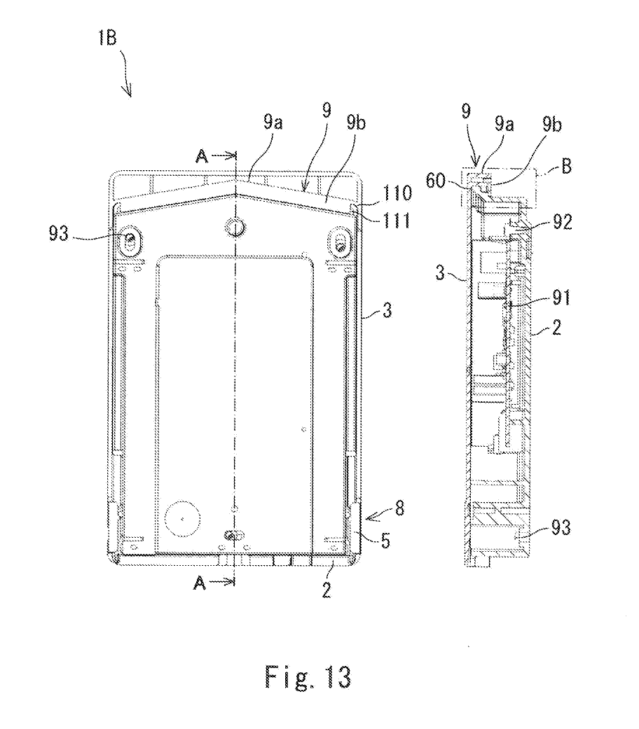

With reference to FIG. 11A, the case body 2 is formed in the shape of a container with a front side opened. The case body 2 is made of a publicly known material such as a plastic resin or metal. The case body 2 can be formed in any shape, and may be formed in a short columnar shape or a short polygonal columnar shape as viewed from the front side, for example. Here, the case body 2 is formed in a rectangular parallelepiped shape. The case body 2 houses an electric board 91. The electric board 91 is attached to the case body 2 with a screw 92 (refer to FIG. 13), for example.

With reference to FIGS. 10A to 10C, the lid 3 is generally formed in the shape of a shallow box with a rear side (back side) and a lower side, being opened. The lid 3 is made of a publicly known material such as a plastic resin or metal. The lid 3 is formed in a shape suitable for the shape of the case body 2. Specifically, the lid 3 includes a body portion 3a in a plate shape for covering the front side of the case body 2, and a waterproof wall portion 9 provided throughout the body portion 3a in width in an upper portion of the body portion 3a. Here, an upper wall portion 3c extending backward is provided at an upper end of the body portion 3a, and the waterproof wall portion 9 is provided below the upper wall portion 3c. The upper wall portion 3c may be omitted, and the waterproof wall portion 9 may constitute an upper wall portion of the body portion 3a. The lid 3 further has a pair of side wall portions 3b extending backward from the corresponding left and right end portions of the body portion 3a.

Hereinafter, configuration of a case 1B for housing an electric board will be separately described sequentially in order of “water entry preventing structure (waterproof structure)” and “fitting structure”. The “water entry preventing structure” is a structure for preventing water from entering the inside of the case body 2 of the case 1B for housing an electric board. The “fitting structure” is a structure in which the lid 3 is fitted and fixed to the case body 2 such that the front side of the case body 2 is covered with the lid 3.

<Water Entry Preventing Structure (Waterproof Structure)>

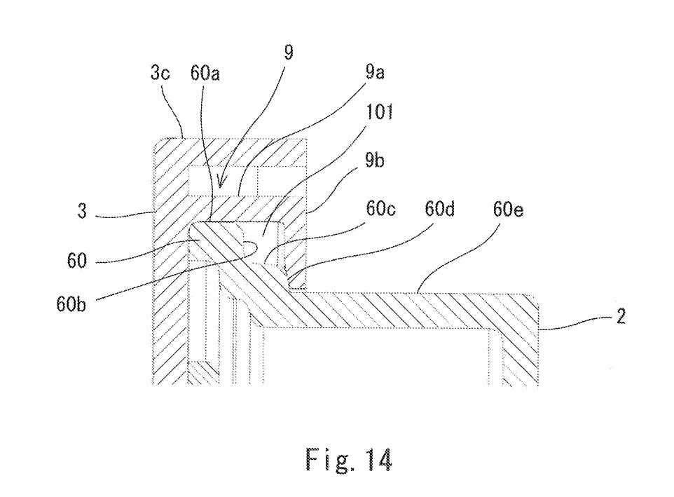

With reference to FIGS. 11B and 14, an upper wall portion 60 of the case body 2 has an upper surface inclining in at least one direction in its lateral direction and formed in a stepped shape descending backward. Here, the phrase, “at least one direction in its lateral direction”, means not only a “left direction” or a “right direction”, but also “left and right directions”. A phrase, “inclining in a certain direction” means “inclining so as to descend toward a certain direction”. Here, the upper surface of the upper wall portion 60 inclines in the left and right directions across a central portion as a vertex. However, the upper surface of the upper wall portion 60 may incline only in the left direction with a right end as a vertex, or may incline only in the right direction with a left end as a vertex.

The upper surface of the upper wall portion 60 formed in a stepped shape may have one or more steps. Here, the upper surface of the upper wall portion 60 is formed in a shape with two steps. The upper surface of the upper wall portion 60 includes an upper end surface 60a, a first stepped surface 60b extending downward from a rear end of the upper end surface 60a, a first step surface 60c extending backward from a lower end of the first stepped surface 60b, a second stepped surface 60d extending downward from a rear end of the first step surface 60c, and a second step surface 60e extending backward from a lower end of the second stepped surface 60d.

Meanwhile, the waterproof wall portion 9 of the lid 3 defines a space 101 serving as a drain channel (hereinafter referred to as a “drain channel”) between the first stepped surface 60b of the upper surface formed in a stepped shape on the upper wall portion 60 of the case body 2 and the waterproof wall portion 9, and is in contact with or close to the second stepped surface 60d below the first stepped surface 60b. Specifically, the waterproof wall portion 9 includes: an extending wall portion 9a that extends backward from a position, above an upper end of the first stepped surface 60b of the case body 2 (the upper end surface 60a of the upper wall portion 60), in the upper portion of the body portion 3a of the lid 3, and that has a lower surface inclining in at least one direction in its lateral direction (here, left and right directions) along an upper surface of the case body 2; and a vertical wall portion 9b that extends downward from a leading end of the extending wall portion 9a, and that has a front surface being in contact with or close to the second stepped surface 60d of the case body 2. This configuration constitutes the waterproof wall portion 9 in which the drain channel 101 is provided between the first stepped surface 60b and the vertical wall portion 9b, and the vertical wall portion 9b is in contact with or close to the second stepped surface 60d, with respect to the upper surface of the upper wall portion 60 of the case body 2, being formed in a stepped shape. A lower surface of the extending wall portion 9a of the waterproof wall portion 9 of the lid 3 and the first step surface 60c of the upper wall portion 60 of the case body 2 constitute an upper wall surface and a bottom wall surface of the drain channel 101, respectively. Then, the first stepped surface 60b and a front surface of the vertical wall portion 9b constitute a front wall surface and a rear wall surface of the drain channel 101, respectively.

FIG. 13 is a rear view and a longitudinal sectional view illustrating a detailed configuration of the case 1B for housing an electric board of FIG. 10A. The longitudinal sectional view shows a section taken along line A-A of the rear view.

With reference to FIGS. 11, 13 and 14, the extending wall portion 9a of the lid 3 is in contact with the upper end surface 60a of the upper surface formed in a stepped shape, of the case body 2. The vertical wall portion 9b has a lower end inclining along an inclination of the upper surface of the case body 2, and has a gap between the second step surface 60e and the vertical wall portion 9b. That is, the lower end of the vertical wall portion 9b of the lid 3 is positioned above the lower end of the second stepped surface 60d.

This configuration causes the lower end of the vertical wall portion 9b not to be brought into contact with the second step surface 60e, so that the extending wall portion 9a of the lid 3 is reliably brought into contact with the upper end surface 60a of the upper surface formed in a stepped shape, of the case body 2. In addition, the drain channel 101 is positioned outside the contact portion in the case 1B for housing an electric board, so that rainwater entry into the case body 2 can be suitably prevented.

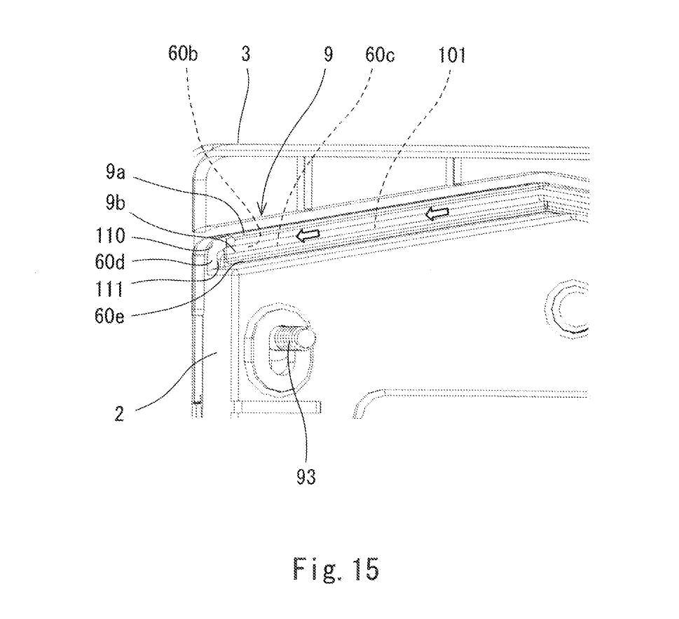

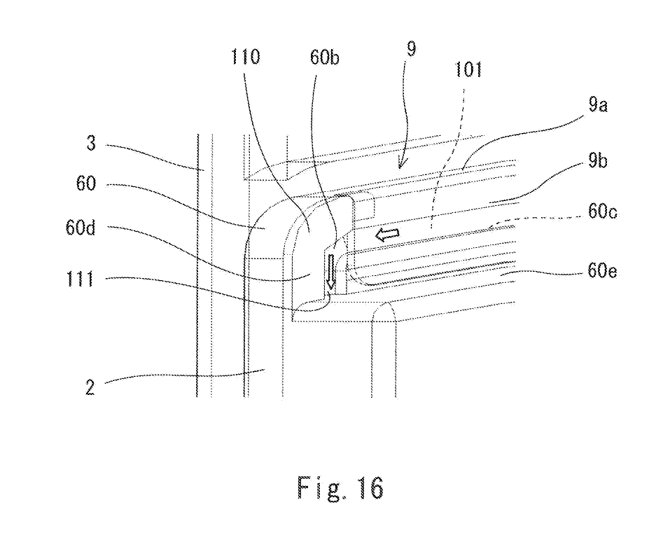

FIG. 15 is a partial perspective view illustrating the drain channel 101 of the case 1B for housing an electric board of FIG. 10A. FIG. 16 is a partial perspective view illustrating a drainage recess 111 of the case 1B for housing an electric board of FIG. 10A. In FIGS. 15 and 16, the lid 3 is drawn transparently for easy understanding of the drain channel 101.

With reference to FIGS. 15 and 16, protrusions 110 extending to the upper end of the upper wall portion 60 are formed at both side end portions of the second stepped surface 60d in the upper surface of the upper wall portion 60 of the case body 2. With reference to FIG. 13, the vertical wall portion 9b of the lid 3 is positioned between the pair of protrusions 110 positioned on both sides in the lateral direction. With reference to FIGS. 15 and 16, the drainage recess 111 is formed in the second stepped surface 60d near the lower end of the drain channel 101 so as to extend downward from the upper end of the second stepped surface 60d. Here, the drainage recess 111 is formed at a position immediately close to the drain channel 101 so as to extend from the upper end to the lower end of the second stepped surface 60d. The drainage recess 111 may be positioned in the middle of the drain channel 101 or slightly away from the drain channel 101 as long as it is close to the lower end of the drain channel 101. The drainage recess 111 also may extend only halfway through the second stepped surface 60d. According to this configuration, water flowing down the drain channel 101 can be discharged to the outside (here, the second step surface 60e) of the case 1B for housing an electric board.

<Fitting Structure>

As described below, a fitting structure 8 includes an engaging portion 5 of the lid 3 and first and second guide portions 61 and 62 of the case body 2.

With reference to FIG. 11A, a front surface of a peripheral wall of the case body 2 is formed flat so as to receive a back surface (rear surface) of the body portion 3a of the lid 3. This enables the lid 3 to be vertically slid relatively to the case body 2.

With reference to FIGS. 10A to 10C, the engaging portion 5 is provided in a lower portion of each of the left and right side wall portions 3b of the lid 3. In side view, the side wall portion 3b is formed so as to project backward from its central portion toward the engaging portion 5. The engaging portion 5 is formed so as to project from the lower portion of the side wall portion 3b to an inner side of the lid 3. The engaging portion 5 is formed in a plate shape, and is formed parallel to a main surface of the body portion 3a of the lid 3. The engaging portion 5 is also provided in its leading end surface with a protrusion 5a having a minute hemispherical shape.

Meanwhile, with reference to FIG. 11B, a first guide portion 61 and a second guide portion 62 are formed in a lower end portion of each of the right and left side surfaces of the case body 2. With reference to FIG. 10C, the first guide portion 61 and the second guide portion 62 are formed at positions corresponding to the engaging portion 5 of the lid 3 when the lid 3 is fitted to the case body 2. With reference to FIG. 11A, the first guide portion 61 is formed so as to project outward from a side surface of the case body 2. The first guide portion 61 has a rear surface formed parallel to an outer surface (refer to FIG. 13) of a bottom wall of the case body 2, and slides relatively to a front surface of the engaging portion 5 of the lid 3 to guide the lid 3.

With reference to FIG. 11B, the second guide portion 62 includes two projections separated from each other formed so as to project outward from respective positions behind the first guide portion 61 in the side surface of the case body 2. With reference to FIGS. 10C and 11B, each of the two protrusions is formed in a trapezoidal shape with rounded corners. The two projections each have a leading end surface formed parallel to the side face of the case body 2, and slide relatively to a leading end surface of the engaging portion 5 of the lid 3 to guide the lid 3. When the lid 3 is fitted to the case body 2, the protrusion 5a of the engaging portion 5 of the lid 3 is engaged with a lower end of the projection on an upper side of the second guide portion 62 of the case body 2, and then the lid 3 is locked to the case body 2. This locking causes the lid 3 to be fixed to the case body 2.

With reference to FIGS. 11A and 11B, a stopper 4 projecting outward is formed at a position above the first guide portion 61 in the side surface of the case body 2. An insertion space 6 is formed between the stopper 4 and the first guide portion 61. The insertion space 6 has a vertical width designed to enable the engaging portion 5 of the lid 3 to be inserted. The stopper 4 restricts upward sliding of the lid 3.

With reference to FIGS. 10A to 10C, an operation portion 7 with a surface roughened is formed in a central portion of the side surface of the lid 3. As a result, a user can grasp the operation portion 7 with one hand to move the lid 3 up and down.

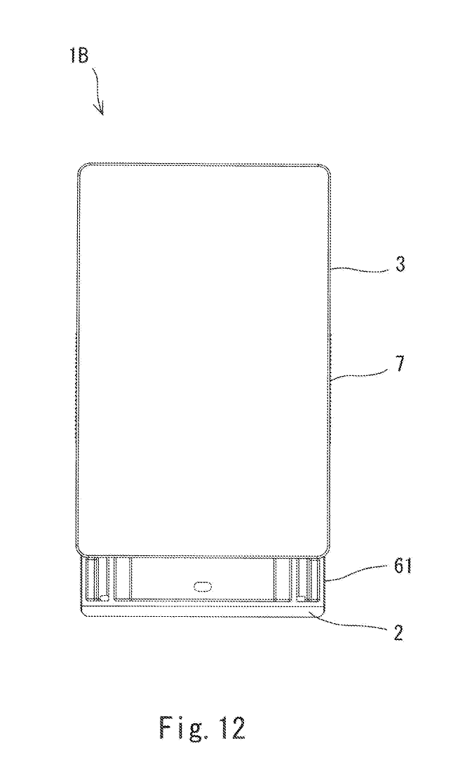

The above configuration enables a user to fit and fix (attach) the lid 3 to the case body 2 as described below. As illustrated in FIG. 12, a user grasps the operation portion 7 by hand, and positions the lid 3 above the case body 2. Then, the engaging portion 5 of the lid 3 is inserted into the insertion space 6 of the case body 2, and the lid 3 is pressed against the case body 2. Next, when the lid 3 is pressed downward, the engaging portion 5 of the lid 3 is slid while being guided by the first guide portion 61 and the second guide portion 62, and then the engaging portion 5 of the lid 3 is fitted to the first guide portion 61 and the second guide portion 62, as illustrated in FIG. 10C. The protrusion 5a of the engaging portion 5 of the lid 3 is then engaged with the lower end of the projection on the upper side of the second guide portion 62 of the case body 2, and the lid 3 is locked to the case body 2. As illustrated in FIG. 14, the lower surface of the extending wall portion 9a of the waterproof wall portion 9 of the lid 3 is then brought into contact with the upper end surface 60a of the upper wall portion 60 of the case body 2. As a result, the lid 3 is fitted and fixed to the case body 2.

[Method of Use]

Subsequently, a method of use of the case 1B for housing an electric board, configured as described above, will be described.

With reference to FIG. 13, the case body 2 is fixed to a mounting place with screws 93. The lid 3 is then fitted and fixed (attached) to the case body 2 using the fitting structure 8, as described above. In the case 1B for housing an electric board, the waterproof wall portion 9 with the leading end extending downward vertically is provided in the upper portion of the lid 3, so that even if the lid 3 is tried to be fitted to the case body 2 from the front side, the leading end of the waterproof wall portion 9 is brought into contact with the upper portion of the case body 2, whereby both the lid 3 and the case body 2 cannot be fitted to each other. However, the fitting structure 8 enables the lid 3 to be fitted and fixed to the case body 2 by sliding the lid 3 downward relatively to the case body 2. In addition, no screw is used to fit the lid to the case body, so that no screw is exposed to an appearance surface. As a result, a design of the case is improved.

With reference to FIGS. 13 to 16, when rainwater falls on the waterproof wall portion 9 of the lid 3 and the second step surface 60e of the upper wall portion 60 of the case body 2 in this state, a capillary phenomenon may cause the rainwater to enter into the inside of the case 1B for housing an electric board through between the second stepped surface 60d and the waterproof wall portion 9. However, even if the rainwater enters in such a way, the rainwater entered exudes into the drain channel 101 between the first stepped surface 60b and the waterproof wall portion 9, and then flows down along an inclination of the first step surface 60c being a bottom surface of the drain channel 101 toward a lateral side of the case body 2. Then, the rainwater is discharged to the outside (the second step surface 60e) of the case 1B for housing an electric board through the drainage recess 111. As a result, rainwater entry into the case body 2 due to a capillary phenomenon can be prevented.

### Another Embodiment

While the case 1A for housing an electric board formed in a vertically elongated rectangular shape has been described as an example in the above-described first embodiment, the shape of the case 1A for housing an electric board is not limited, and thus may be a shape other than that of the above-described first embodiment, such as a horizontally elongated rectangular shape, or a square shape.

While an example of using the head portion 34 of the detachable screw member 33 as the protrusion 32 of the restricting portion 30 has been described in the above-described first embodiment, another component having similar function (e.g., a protrusion member) as the protrusion 32 is available, and thus configuration of the restricting portion 30 is not limited to that of the above-described first embodiment.

The fitting structure 8 of the above-described second embodiment may be omitted. In this case, for example, the lid 3 is to be fixed to the case body 2 with a fixture such as a screw. The lid 3 is operated by a user so that the waterproof wall portion 9 engages with the upper portion of the case body 2 to fit the lid 3 to the case body 2, and then the lid 3 may be fixed to the case body 2 with the fixture.

In addition, the fitting structure 8 of the above-described second embodiment may be modified as follows. For example, the upper surface of the upper wall portion 60 of the case body 2 and the waterproof wall portion 9 of the lid 3 may be configured to incline from the left end or the right end to the other end so that the lid 3 is fitted to the case body 2 by sliding the lid 3 toward the left end or the right from the other end relatively to the case body 2.

From the above description, many modifications and other embodiments of the present invention are apparent to a person skilled in the art. Thus, the above description is to be construed only as illustrative examples, and is provided for a purpose of teaching the best mode of practicing the invention to a person skilled in the art. Details of structure and/or function of the present invention can be substantially changed without departing from the spirit of the present invention.

### INDUSTRIAL APPLICABILITY

The case for housing an electric board of the present invention is useful for a case for housing an electric board in which a structure for restricting opening operation of a lid is provided between a case body and the lid to prevent the lid from being easily opened without degrading a design of the case for housing an electric board.

The case for housing an electric board of the present invention is also useful for a case for housing an electric board, being capable of preventing rainwater entry into the inside of the case body due to a capillary phenomenon.

### DESCRIPTION OF THE REFERENCE NUMERALS

1A, 1B case
2 case body
3 lid
3a body portion
3b side wall portion
3c upper wall portion
4 stopper
5 engaging portion
6 insertion space
7 operation portion
8 fitting portion
9 waterproof portion
9a extending wall portion
9b vertical wall portion
10 case body
11 guide portion
12 locking portion
13 opening
14 locking stepped portion
15 rear wall
16 housing portion
17 insertion portion
18 screw seat
20 lid
21 sliding portion
22 engaging portion
23 inner surface
24 engaging steeped portion
25 relief
26 gripping portion
30 restricting portion
31 recess
32 protrusion
33 detachable screw member
34 head portion
40 electric board
41 IC card
42 connector
50 attachment surface
60 upper wall portion
60a upper end surface
60b first stepped surface
60c first step surface
60d second stepped surface
60e second step surface
61 first guide portion
62 second guide portion
91 electric board
92 screw
93 screw
101 drain channel
110 protrusion
111 drainage recess

1. A case for housing an electric board, the case comprising:
a case body with a front side opened for housing an electric board inside the case body,
a lid that closes the front side of the case body, and
a restricting portion provided between an inner surface of the lid and the case body to restrict sliding movement of the lid in an opening direction of the lid,
the case body including
a guide portion for sliding and moving a lid parallel to the front side, and
a locking portion that locks the lid slid along the guide portion, and
the lid including
a sliding portion that slides along the guide portion, and
an engaging portion that engages with the locking portion while the front side of the case body is closed.

2. The case for housing an electric board, according to claim 1, wherein
the restricting portion includes a recess provided in at least one of the case body and the lid, and a protrusion provided in the other of the case body and the lid at a position corresponding to the recess in a state in which the lid is closed.

3. The case for housing an electric board, according to claim 2, wherein
the protrusion is configured to be detachable.

4. The case for housing an electric board, according to claim 2, wherein
the protrusion is configured to be capable of adjusting a height of the protrusion protruding toward the recess.

5. The case for housing an electric board, according to claim 2, wherein
the protrusion is formed of a screw member with a head portion.

6. The case for housing an electric board, according to claim 5, wherein
the screw member serves as a fixing screw member for fixing the case body to a mounting surface.

7. A case for housing an electric board, the case comprising:
a case body in a container shape with a front side opened for housing an electric board inside the case body,
the case body including
an upper wall portion with an upper surface inclining in at least one direction in a lateral direction, and formed in a stepped shape descending backward in an anteroposterior direction; and
a lid for covering the front side of the case body,
the lid including
a waterproof wall portion that defines a space serving as a drain channel between a first stepped surface of the upper surface formed in a stepped shape and the waterproof wall portion, and that is in contact with or close to a second stepped surface below the first stepped surface.

8. The case for housing an electric board, according to claim 7, wherein
the lid includes a body portion in a plate shape for covering the front side of the case body, and the waterproof wall portion provided in a upper portion of the body portion,
the waterproof wall portion includes an extending wall portion extending backward from a position, above an upper end of the first stepped surface, in the upper portion of the body portion, and having a lower surface inclining in at least one direction in the lateral direction along an upper surface of the case body, and a vertical wall portion extending downward from a leading end of the extending wall portion, and having a front surface being in contact with or close to the second stepped surface.

9. The case for housing an electric board, according to claim 7, wherein
the case body includes a drainage recess formed in the second stepped surface near a lower end of the space so as to extend downward from an upper end of the second stepped surface.

10. The case for housing an electric board, according to claim 8, wherein
the extending wall portion of the lid is brought into contact with an upper end surface of the upper surface formed in a stepped shape of the case body, and
the vertical wall portion has a lower end positioned above a lower end of the second stepped surface.

11. The case for housing an electric board, according to claim 7, further comprising:
a fitting structure in which the lid is fitted to the case body by sliding the lid downward relatively to the case body.

12. The case for housing an electric board, according to claim 8, wherein
the case body includes a drainage recess formed in the second stepped surface near a lower end of the space so as to extend downward from an upper end of the second stepped surface.

13. The case for housing an electric board, according to claim 8, further comprising:
a fitting structure in which the lid is fitted to the case body by sliding the lid downward relatively to the case body.

14. The case for housing an electric board, according to claim 3, wherein
the protrusion is configured to be capable of adjusting a height of the protrusion protruding toward the recess.

15. The case for housing an electric board, according to claim 3, wherein
the protrusion is formed of a screw member with a head portion.
